(19) United States
(12) Patent Application Publication
(10) Pub. No.: US 2018/0315911 A1
(43) Pub. Date: Nov. 1, 2018

(54) Electrical-Contact Assemblies

(71) Applicant: Heptagon Micro Optics Pte. Ltd., Singapore (SG)

(72) Inventors: Bojan Tesanovic, Steinhausen (CH); Peter Riel, Bach (CH)

(21) Appl. No.: 15/769,893

(22) PCT Filed: Oct. 24, 2016
(86) PCT No.: PCT/SG2016/050517

§ 371 Date: Apr. 20, 2018

Related U.S. Application Data
(60) Provisional application No. 62/245,644, filed on Oct. 23, 2015.

(51) Int. Cl. H01L 33/62; H01L 31/02; H01L 33/54; H01L 31/0203; H01L 33/58; H01L 31/0232; H01L 31/18

(52) U.S. Cl. CPC H01L 33/62; H01L 31/02005; H01L 33/54; H01L 2933/0066; H01L 33/58; H01L 31/02327; H01L 31/18; H01L 31/0203

(57) ABSTRACT

An electrical-contact assembly includes electrical contacts with first and second electrical-contact surfaces on opposing sides of the assembly. The electrical-contact assembly is manufactured by a structurable process (e.g., photo-structurable process) and by electroplating. The first and second electrical-contact surfaces can be positioned with respect to each other with an accuracy, for example, of at least 5 microns. Further, the thickness of the electrical-contact assembly can be at most 17 microns in some cases. The electrical-contact assembly can include integrated active optoelectronic elements, overmolds, optical elements and non-transparent walls.

### TECHNICAL FIELD

This disclosure relates to electrical-contact assemblies and pluralities of electrical-contact assemblies.

### BACKGROUND

Typically an electronic device is electrically mounted to a printed circuit board (PCB) via electrical contacts. The PCB can then be mounted electrically to a host device, thereby electrically connecting the electronic device to the host device. Electrical contacts are often implemented by using vias fabricated through the PCB. The fabrication of misalignment-free vias, however, is a challenging task for large-scale, low-cost manufacturing. Misalignment-free vias fabricated with an intentional offset can be difficult to fabricate. Further, the movement to manufacture smaller and smaller host devices, such as portable, handheld computational devices, has generated the need for particularly thin PCBs with precisely placed vias and other electrical contacts.

### SUMMARY

This disclosure describes electrical-contact assemblies, and methods for making the same. The electrical-contact assemblies can be fabricated with particularly thin dimensions. Further, the electrical-contact assemblies can be fabricated with misalignment-free electrical contacts in some cases. In some implementations, the electrical-contact assemblies overcome the challenges and limitations described above.

For example, in one aspect, an electrical-contact assembly includes a plurality of electrical contacts each of which is substantially electrically conductive and has a first electrical-contact surface and a second electrical-contact surface respectively disposed on opposing sides of the electrical contact. The electrical contacts are interposed by a plurality of electrical insulators that are substantially electrically insulating.

Some implementations include one or more of the following features. For example, in some cases, the electrical-contact assembly includes at least one electrical contact with offset first and second electrical-contact surfaces. The offset first and second electrical-contact surfaces can be positioned with an accuracy, for example, of at least 5 microns.

In some instances, the electrical-contact assembly includes a plurality of electrical insulators, at least partially, composed of curable epoxy resin. The electrical contacts can be arranged such that curable epoxy resin conforms to the electrical contacts.

In some instances, the electrical-contact assembly includes at least one electrical insulator, within a plurality of electrical insulators, that extends around at least one first electrical-contact surface. The electrical insulator forms sidewalls, where the sidewalls delineate a chamber associated with at least one first electrical-contact surface. The electrical insulator has contiguous sidewalls with its smaller dimension located in a direction orthogonal to electrical-contact surfaces of the electrical contacts.

In some cases, the electrical-contact assembly includes a plurality of electrical contacts, each of which is substantially electrically conductive. Each electrical contact can have a first electrical-contact surface and a second electrical-contact surface respectively disposed on opposing sides of the electrical contact. The electrical contacts are interposed by a plurality of electrical insulators that are substantially electrically insulating. Moreover, the electrical insulators can be at least partially composed of a mechanically robust structurable layer.

In some implementations, the mechanically robust structurable layer includes fibers or particles dispersed within a photo-resist. Mechanically robust structurable layers can be incorporated into an electrical-contact assembly during manufacturing. The electrical-contact assembly can have minimal dimensions, with its smallest dimension located in a direction orthogonal to the electrical-contact surfaces of a plurality electrical contacts.

In some cases, at least one sidewall element is mounted on a surface of the mechanically robust structurable layer, where the at least one sidewall element delineates a chamber associated with at least one first electrical-contact surface.

In some instances, at least one of a first electrical-contact surface includes an active optoelectronic component electrically connected to the at least one first electrical-contact surface.

In some instances, the electrical-contact assembly has a sidewall element that is substantially non-transparent to electromagnetic radiation emitted by or detectable by an active optoelectronic component.

In some implementations, at least one of a first electrical-contact surface includes an active optoelectronic component electrically connected to the at least one first electrical-contact surface.

In some cases, the active optoelectronic component includes an emitter and/or a detector, and an overmold of transparent material. The overmold of transparent material can protect the active optoelectronic component from dust, moisture, or other foreign matter.

In another example aspect, a surface of the transparent overmold delineates an optical element. The transparent overmold can permit an electrical-contact assembly to exhibit a particularly thin dimension in a direction orthogonal to a direction orthogonal to electrical-contact surfaces of electrical contacts.

In another aspect, a method for manufacturing an electrical-contact assembly or a plurality of electrical-contact assemblies includes: applying a conductive layer to a surface of a substrate; applying electrical contacts to the conductive layer; applying a first structurable layer to a surface of the conductive layer; subjecting the first structurable layer to a structuring treatment, the treatment establishing structure boundaries; subjecting the first structurable layers to a developing treatment such that structures defining negatives of electrical contacts are formed by the first structurable layer and the conductive layer; electroplating the conductive layer such that the negatives are filled with plating material whereby electrical contacts are formed within the negatives; removing the first structurable layers; mounting the substrate, conductive layer, and electrical contacts into a tool wherein the tool includes conduits for directing formable material in-between the electrical contacts, the formable material defining electrical insulators; removing the substrate from the conductive layer, the electrical contacts and the electrical insulators; and singulating electrical contacts along singulation lines.

Some implementations include one or more of the following features. For example, for the method includes manufacturing the conductive layer to allow the conductive layer to be particularly thin.

In some cases, manufacturing the structurable layer allows the thickness of the structurable layer to be customized during manufacturing.

In some instances, manufacturing the structurable layer allows the thickness of the structurable layer to be particularly thin. For example, the thickness of the structurable layer can be no more than 17 microns in some cases.

In some implementations, a structuring treatment allows highly accurate positioning of subsequently plated electrical contacts. The accuracy of the positioning can be, for example, at least 5 microns.

In some instances, the method for manufacturing an electrical-contact assembly is implemented on a wafer scale (e.g., 10s, 100s, or 1000s of electrical contacts are manufactured at a time).

In some cases, the method for manufacturing an electrical-contact assembly includes: applying a conductive layer to a surface of a substrate; applying electrical contacts to the conductive layer; applying a first structurable layer to a surface of the conductive layer; subjecting the first structurable layer to a structuring treatment, the treatment establishing structure boundaries; applying a second structurable layer to a surface of the first structurable layer; subjecting the second structurable layer to a structuring treatment, the treatment establishing structure boundaries; subjecting the first and second structurable layers to a developing treatment such that structures defining negatives of electrical contacts are formed by the first and second structurable layers and the conductive layer; electroplating the conductive layer such that the negatives are filled with plating material whereby electrical contacts are formed within the negatives; removing the first and second structurable layers; mounting the substrate, conductive layer, and electrical contacts into a tool wherein the tool includes conduits for directing formable material in-between the electrical contacts, the formable material defining electrical insulators; removing the substrate from the conductive layer, the electrical contacts and the electrical insulators; and singulating electrical contacts along singulation lines. In such implementations, electrical contacts having first and second electrical-contact surfaces, respectively disposed on opposing sides of the electrical contacts, are respectively offset in some instances. The offset has an accuracy of 5 microns or less in some instances. The method can be implemented on a wafer scale (e.g., 10s, 100s, or 1000s of electrical contacts are manufactured at a time).

In some implementations, the method for manufacturing an electrical-contact assembly includes: applying a conductive layer to a surface of a substrate; applying electrical contacts to the conductive layer; applying a first robust structurable layer to a surface of the conductive layer; subjecting the first robust structurable layer to a structuring treatment, the treatment establishing structure boundaries; subjecting the first robust structurable layer to a developing treatment such that structures defining negatives of electrical contacts are formed by the first and second robust structurable layers and the conductive layer; electroplating the conductive layer such that the negatives are filled with plating material whereby electrical contacts are formed within the negatives; mounting the substrate, conductive layer, the first structurable layers, and electrical contacts into a tool wherein the tool includes conduits for directing formable material to form sidewall elements on a side of the electrical contacts having first electrical-contact surfaces; removing the substrate from the conductive layer, the electrical contacts and the electrical insulators; and singulating electrical contacts along singulation lines. The method can be implemented on a wafer scale (e.g., 10s, 100s, or 1000s of electrical contacts are manufactured at a time).

In some instances, a method for manufacturing an electrical-contact assembly includes: applying a conductive layer to a surface of a substrate; applying electrical contacts to the conductive layer; applying a first robust structurable layer to a surface of the conductive layer; subjecting the first robust structurable layer to a structuring treatment, the treatment establishing structure boundaries; applying a second robust structurable layer to a surface of the first robust structurable layer; subjecting the second robust structurable layer to a structuring treatment, the treatment establishing structure boundaries; subjecting the first and second robust structurable layers to a developing treatment such that structures defining negatives of electrical contacts are formed by the first and second robust structurable layers and the conductive layer; electroplating the conductive layer such that the negatives are filled with plating material whereby electrical contacts are formed within the negatives; mounting the substrate, conductive layer, the first and second robust structurable layers, and electrical contacts into a tool wherein the tool includes conduits for directing formable material to form sidewall elements on a side of the electrical contacts having first electrical-contact surfaces; removing the substrate from the conductive layer, the electrical contacts and the electrical insulators; and singulating electrical contacts along singulation lines. The method can be implemented on a wafer scale (e.g., 10s, 100s, or 1000 s of electrical contacts are manufactured at a time).

In some instances, the method for manufacturing an electrical-contact assembly includes: applying a releasable layer to a surface of a substrate, the releasable layer being between a conductive layer and the substrate; and removing the substrate from electrical contacts and electrical insulators by releasing the releasable layer.

In some cases, the method for manufacturing an electrical-contact assembly includes subjecting a structurable layer or robust structurable layer to selective irradiation.

In some implementations, the method for manufacturing an electrical-contact assembly includes irradiating the releasable layer with radiation such as ultraviolet radiation and/or infrared radiation is other instances.

In some cases, the method for manufacturing an electrical-contact assembly includes providing a substrate that is substantially transparent to ultra-violet and/or infrared radiation.

Other aspects, features and advantages will be readily apparent from the following detailed description, the accompanying drawings, and the claims.

### BRIEF DESCRIPTION OF THE DRAWINGS

FIG. 1A-FIG. 1F depict example electrical-contact assemblies.

FIG. 2A depicts an example process flow for manufacturing electrical-contact assemblies.

FIG. 2B-FIG. 2D depict various process steps executed in the example process flow depicted in FIG. 2A.

FIG. 3A depicts another example process flow for manufacturing electrical-contact assemblies.

FIG. 3B depicts various process steps executed in the example process flow depicted in FIG. 3A.

FIG. 4 depicts still another example process flow for manufacturing electrical-contact assemblies.

### DETAILED DESCRIPTION

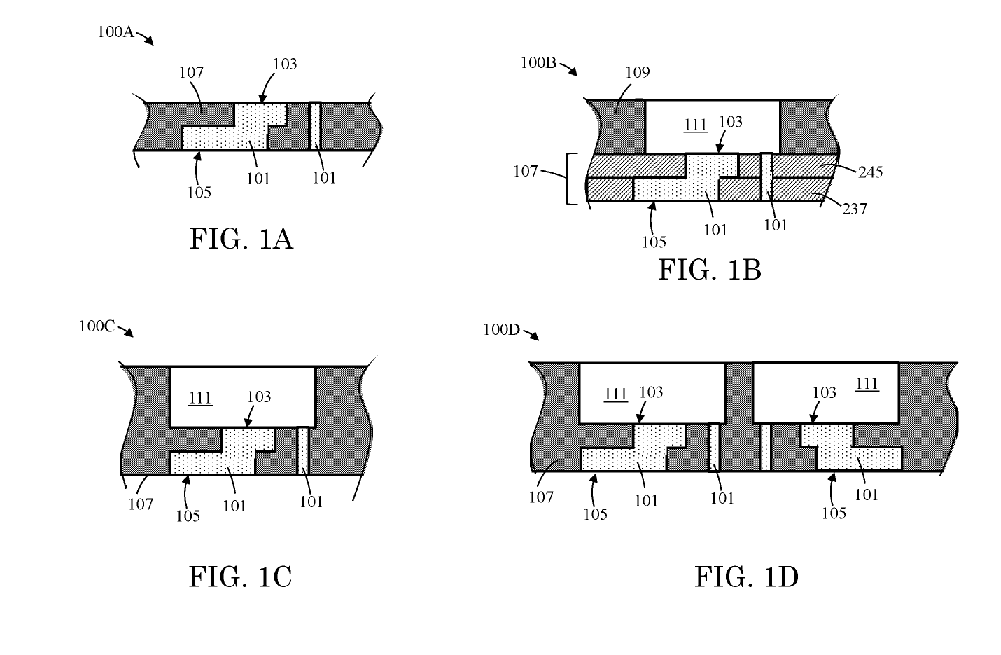

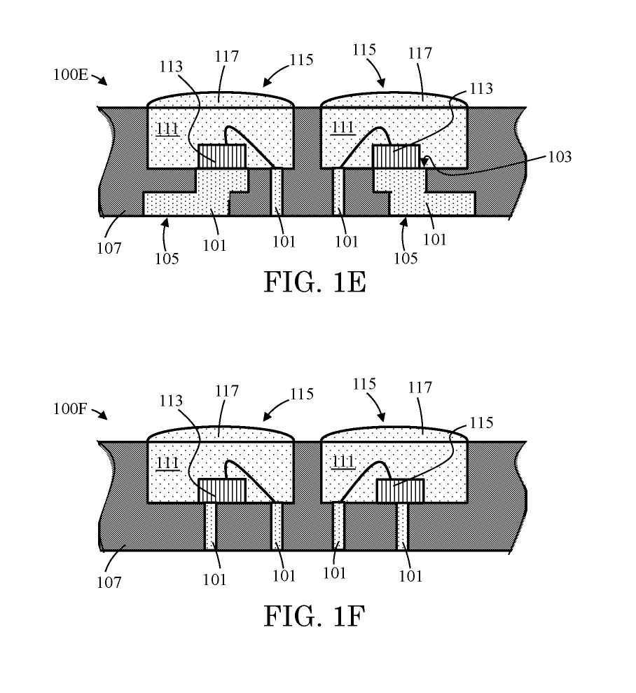

FIG. 1A depicts an example of an electrical-contact assembly 100A. The electrical-contact assembly 100A includes electrical contacts 101. Each electrical contact 101 includes a first electrical-contact surface 103 and a second electrical-contact surface 105 respectively disposed on opposing sides of the electrical contacts 101. The electrical-contact assembly 100 further includes electrical insulators 107 interposed between the electrical contacts 101 such that the electrical contacts 101 are electrically insulated from each other. The example implementations illustrated in FIG. 1A-FIG. 1F illustrate at least one of the electrical contacts 101 with the first electrical-contact surface 103 and the second electrical-contact surface 105 offset from each other (cf. FIG. 1A left-hand electrical contact 101). However, the electrical contacts 101 need not have offset first and second electrical-contact surfaces 103, 105, respectively. The electrical contacts 101 are substantially electrically conducting and can be manufactured by electroplating. Substantially electrically conducting is used herein to indicate that reasonable performance of the electrically conducting component for a given application can be expected by a person of ordinary skill in the art to which this disclosure pertains. The electrical contacts 101 can be at least partially composed of any number of suitable metals or their respective alloys (e.g., metals such as copper, nickel, iron, tin, silver, gold, zinc, palladium, rhodium, platinum) and/or metal alloys containing non-metals such as steel. The electrical insulators 107 are electrically insulating and can be at least partially composed of any polymeric material with suitable electrically insulating properties such as an epoxy resin. In some instances, the electrical insulators 107 can include other materials such as inorganic or organic additives or fillers, such as carbon. In some implementations, electrical insulators 107 can be substantially non-transparent to a particular wavelength or ranges of wavelengths of electromagnetic radiation. Substantially non-transparent is used herein to indicate that reasonable performance of the non-transparent component for a given application can be expected by a person of ordinary skill in the art to which this disclosure pertains. In some implementations, the electrical contacts 101 and the electrical insulators 107 can be manufactured with particularly thin dimensions such as 17 microns or even smaller. While in other implementations the electrical insulators 107 can be manufactured with larger dimensions, such as 50 microns or even hundreds of microns. In various implementations the electrical contacts 101 and the electrical insulators 107 can be positioned with particularly high accuracy such as within 5 microns. Further, the first and second electrical-contact surfaces can be positioned with particularly high accuracy such as within 5 microns.

FIG. 1B depicts another example of an electrical-contact assembly. An electrical-contact assembly 100B includes the electrical contacts 101, the first electrical-contact surfaces 103, and the second electrical-contact surfaces 105 described above. In this implementation the electrical insulators 107 include a first structurable layer 237 and a second structurable layer 245. The first structurable layer 237 and second structurable layer 245 can be at least partially composed of a developed photo-structurable material (e.g., a photo-resist). The first structurable layer 237 and the second structurable layer 245 can be substantially electrically insulating and can include additives or other components for improving the mechanical properties of the first structurable layer 237 and second structurable layer 245 (e.g., to improve the robustness of the first structurable layer 237 and second structurable layer 245). Substantially electrically insulating is used herein to indicate that reasonable performance of the electrically insulating component for a given application can be expected by a person of ordinary skill in the art to which this disclosure pertains. Such additives or other components can include glass fibers, glass particles, or other materials capable of imparting robustness to the first and second structurable layers 237, 245, respectively. The electrical-contact assembly 100B further includes a sidewall element 109. The sidewall element 109 can be at least partially composed of any polymeric material such as an epoxy resin. In some instances, the sidewall element 109 can include other materials such as inorganic or organic additives or fillers, such as carbon. In some implementations sidewalls element 109 can be substantially non-transparent to a particular wavelength or ranges of wavelengths of electromagnetic radiation. Substantially non-transparent to a particular wavelength is used herein to indicate that reasonable performance of the non-transparent component for a given application can be expected by a person of ordinary skill in the art to which this disclosure pertains. The sidewalls element 109 can partially delineate peripheral boundaries of a chamber 111.

FIG. 1C depicts another example of an electrical-contact assembly. An electrical-contact assembly 100C includes the electrical contacts 101, the first electrical-contact surfaces 103, and the second electrical-contact surfaces 105 described above. The electrical-contact assembly 100C further includes electrical insulators 107 as described above but with an extension forming sidewalls of a chamber 111.

FIG. 1D depicts another example of an electrical-contact assembly. An electrical-contact assembly 100D includes a plurality of electrical contacts 101, a plurality of first electrical-contact surfaces 103, a plurality of second electrical-contact surfaces 105, a plurality of electrical insulators 107, and a plurality of chambers 111 as described above. Such implementations can be incorporated into optoelectronic modules such as proximity modules, computational cameras, and three-dimensional cameras.

FIG. 1E depicts another example of an electrical-contact assembly. An electrical-contact assembly 100E includes a plurality of electrical contacts 101, a plurality of first electrical-contact surfaces 103, a plurality of second electrical-contact surfaces 105, a plurality of electrical insulators 107, and a plurality of chambers 111 as described above. The electrical-contact assembly 100E further includes multiple active optoelectronic components 113. The active optoelectronic components 113 can include any of a number of active optoelectronic components or their combination, for example, vertical-cavity surface-emitting lasers, other laser diodes, photodiodes, light-emitting diodes, imaging sensors (such as charge-couple devices or complementary metal oxide semi-conductor devices). Indeed, although multiple active optoelectronic components 113 are depicted, a single optoelectronic component 113 can be included in some implementations. For example, the example electrical-contact assemblies described above (cf. FIG. 1A-FIG. 1C) can include only a single active optoelectronic component in some implementations. The electrical-contact assemblies 100E further includes a transparent overmold 115 incorporated into each chamber 111. The transparent overmold 115 can be at least partially composed of any material suited to the particular function of the electrical-contact assemblies 100E. For example, the transparent overmold 115 can be at least partially composed of material that is substantially transparent to electromagnetic radiation (i.e., light) emitted or detected by the active optoelectronic components 113 (e.g., transparent silicones, transparent epoxy resins, or other transparent polymers). Still in some implementations the transparent overmold 115 can be at least partially composed of a transparent material and can also include an additive or other components, such as a dye, for filtering.

FIG. 1F depicts another example of an electrical-contact assembly. An electrical-contact assembly 100F includes the components described above, however, while in the previous examples some of the electrical contacts 101 are offset, the electrical contacts 101 in electrical-contact assemblies 100F are not offset. Accordingly, in various implementations the electrical contacts can be offset or need not be offset.

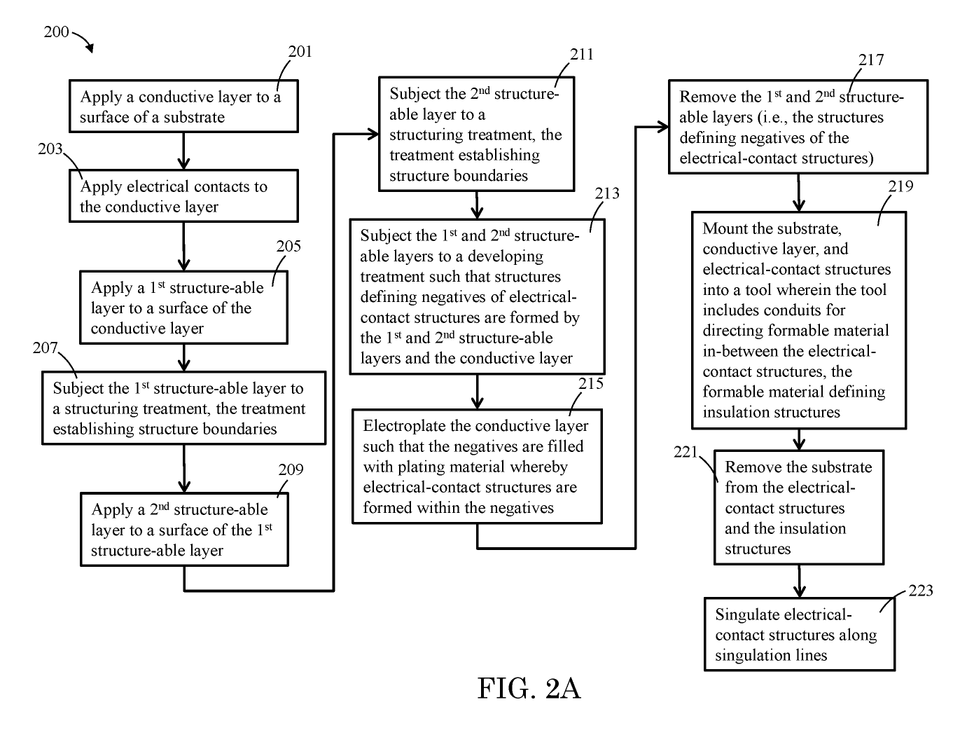

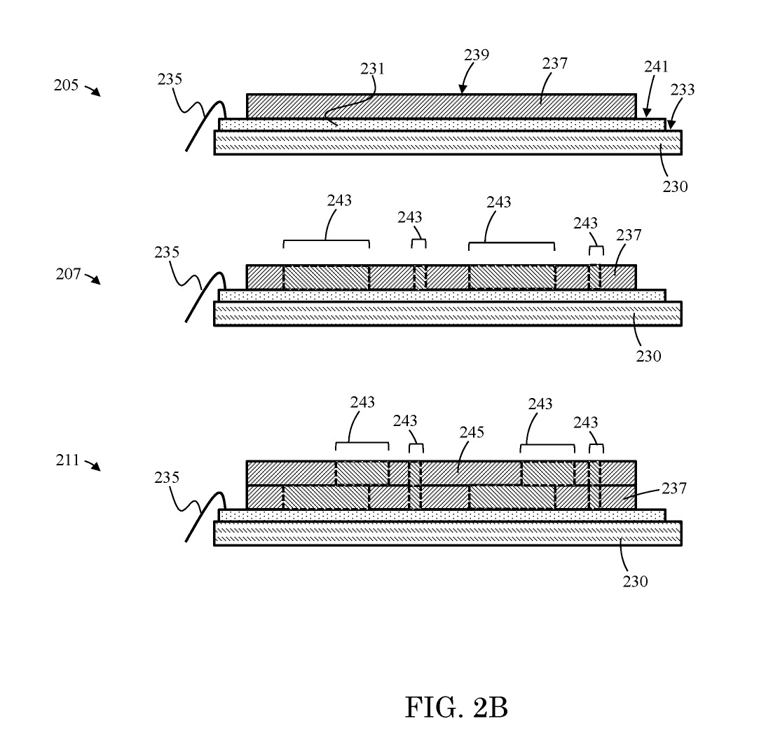

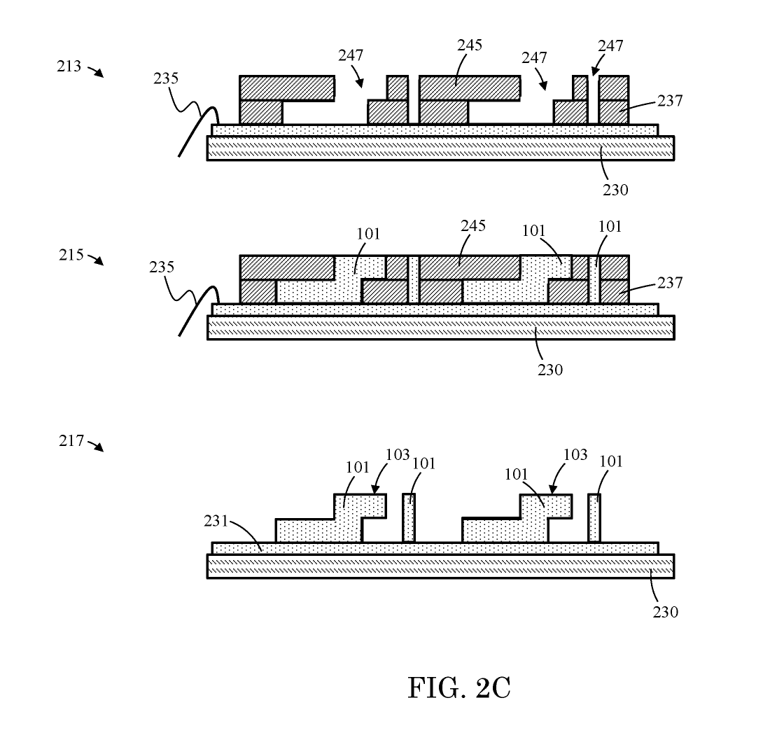

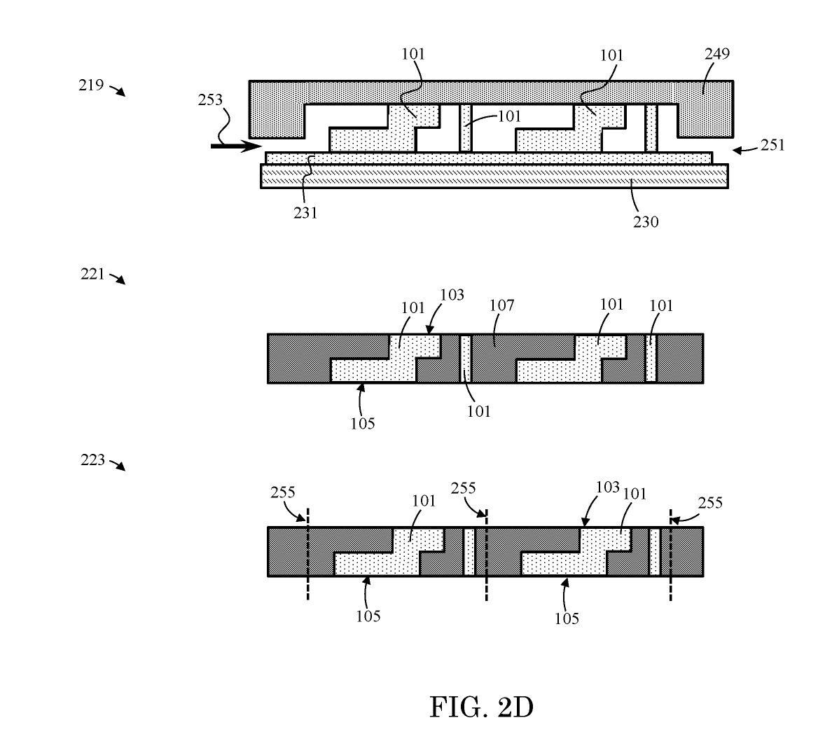

FIG. 2A depicts an example process flow for manufacturing electrical-contact assemblies. A method for manufacturing an electrical-contact assembly 200 includes a number of manufacturing the steps. In a first step 201 (as depicted in FIG. 2A) a conductive layer 231 can be applied to a substrate 230. The conductive layer 231 can be at least partially composed of any number of suitable metals or their respective alloys (e.g., metals such as copper, nickel, iron, tin, silver, gold, zinc, palladium, rhodium, platinum) and/or metal alloys containing non-metals such as steel. The conductive layer can be applied to the substrate 230 by any suitable means (e.g., sputtering or other deposition techniques). The substrate 230 can be any suitable material such as a glass wafer. In general, the substrate 230 should be substantially resistant to solutions (e.g., acids, developing solutions, and plating solutions) in subsequent steps.

In another step 203, electrodes 235 can be applied to a surface of the conductive layer 233. The electrical contact can be at least partially composed of any electrically conducting material such as any number of suitable metals or their respective alloys (e.g., metals such as copper, nickel, iron, tin, silver, gold, zinc, palladium, rhodium, platinum) and/or metal alloys containing non-metals such as steel. Application of the electrodes 235 to the conductive layer 231 can be accomplished by any suitable means (e.g., soldering).

In another step 205 a first structurable layer 237 can be applied to a surface of the conductive layer 241. The first structurable layer 237 can be at least partially composed of any material that can be structured (e.g., a photo-structurable material such as a photoresist). The first structurable layer 237 can be particularly thin, for example, in some implementations the first structurable layer 237 can be 17 microns thick, while in other implementations the first structurable layer 237 can be even less than 17 microns thick. Still further, in other implementations the first structurable layer 237 can be thicker, for example 50 microns or even hundreds of microns thick. The first structurable layer 237 can be applied to the conductive layer surface 241 as a foil in some implementations, while in other implementations the first structurable layer 237 can be applied with spin coating, evaporation, or any other suitable means apparent to a person of ordinary skill in the art in light of this disclosure.

In another step 207 the first structurable layer 237 can be subjected to a structuring treatment, where the treatment establishes structure boundaries 243. The structuring treatment can include irradiating the first structurable layer 237 with electromagnetic radiation (e.g., ultraviolet radiation and/or infrared radiation) in implementations where the first structurable layer 237 is implemented as a photoresist or other photo-structurable material. In such implementations the portions of the first structurable layer 237 that are irradiated with electromagnetic radiation can establish structure boundaries 243. The structure boundaries 243 can be positioned with patriotically high accuracy, for example, 5 microns or even less. The accuracy of the structure boundaries 243 positioning contributes to the accuracy in dimensioning and positioning of the electrical contacts 101.

In another step 209 a second structurable layer 245 can be applied to a surface of the first structurable layer 237. As above, the second structurable layer 245 can be at least partially composed of any material that can be structured (e.g., a photo-structurable material such as a photoresist). The second structurable layer 245 can be particularly thin, for example, in some implementations the second structurable layer 245 can be 17 microns thick, while in other implementations the second structurable layer 245 can be even less than 17 microns thick. Still further, in other implementations the second structurable layer 245 can be thicker, for example 50 microns or even hundreds of microns thick. The second structurable layer 245 can be applied to the first structurable layer surface 239 as a foil in some implementations, while in other implementations the second structurable layer 245 can be applied with spin coating, evaporation, or any other suitable means apparent to a person of ordinary skill in the art in light of this disclosure.

In another step 211 the second structurable layer 245 can be subjected to a structuring treatment, where the treatment establishes additional structure boundaries 243. The structure boundaries 243 can be positioned with patriotically high accuracy, for example, 5 microns or even less. The accuracy of the structure boundaries 243 positioning contributes to the accuracy in dimensioning and positioning of the electrical contacts 101. In some implementations some of the additional structure boundaries 243 can be established at an offset from the structure boundaries 243 within the first structurable layer 237. The structuring treatment can include irradiating the second structurable layer 245 with electromagnetic radiation (e.g., ultraviolet radiation and/or infrared radiation) in implementations where the second structurable layer 245 is implemented as a photoresist or other photo-structurable material. In such implementations the portions of the second structurable layer 245 that are irradiated with electromagnetic radiation can establish the additional structure boundaries 243.

In another step 213, the first and second structurable layers 237, 245, respectively are subjected to a developing treatment. The developing treatment can delineate negatives of electrical contacts 101. The negatives of the electrical contact structures are formed by the first and second structurable layers and the conductive layer 213. Generally, the developing treatment removes some material (e.g., the material that was subjected to the structuring treatment described above), the removed material forming the negatives, described above, of the electrical contacts 101.

In another step 215 the conductive layer is subjected to an electroplating treatment whereby metal is deposited onto the surface of the conductive layer 231. The metal (i.e., plating material) can be any number of suitable metals or their respective alloys (e.g., metals such as copper, nickel, iron, tin, silver, gold, zinc, palladium, rhodium, platinum) and/or metal alloys containing non-metals such as steel. The step 215 is carried out until a desired thickness of metal is reached, in particular until the negatives (described above) are substantially fully occupied with plating material, wherein the plating material substantially fully occupying the negatives delineates the electrical contacts 101.

In another step 217, the first and second structurable layers 237, 245, respectively are removed. For example, in some implementations, the first and second structurable layers 237, 245, respectively are removed using acids. While in other implementations the first and second structurable layers 237, 245, respectively are removed using other solutions (e.g., bases or other solvents such as organic solvents).

In another step 219 the substrate 230, the conductive layer 231, and the electrical contacts 101 can be mounted into a tool 249. The tool 249 can contain conduits for directing formable material 253 (e.g., liquid polymers, resins or other molding compounds) in between the electrical contacts 101. In some implementations the formable material 253 can be directed into the tool 249 under pressure. In some implementations the formable material 253 can be directed in the tool 249 by using a vacuum. While in some implementations the formable material 253 can be directed into the tool 249 with the application of heat. The formable material 253 can be subsequently cured (e.g., by ultraviolet or thermal treatments). Accordingly, upon curing the formable material 253, the tool 249 can be removed.

In another step 221, the substrate 230 and the conductive layer 231 can be removed from the electrical contacts 101 and the electrical insulators 107. While in other implementations the substrate 230 can be removed from the conductive layer 231, the electrical contacts 101 and the electrical insulators 107. In some implementations the substrate 230 and the conductive layer 231, and/or the substrate 230 can be removed mechanically (e.g., with the application of a shearing force) as would be apparent to a person of ordinary skill in the art in light of this disclosure. Subsequent to separation of the substrate 230 from the conductive layer 231, the electrical contacts 101, and the electrical insulators 107, the conductive layer 231 can be removed by other treatments (e.g., via grinding, polishing or by chemical methods such as etching with acidic or caustic solutions).

In some implementations, in another step 223 the electrical contacts 101 are singulated into discrete electrical-contact assemblies 100 by techniques known to a person of ordinary skill in the art in light of this disclosure.

FIG. 2B depicts various process steps executed in the example process flow 200 depicted in FIG. 2A. The upper portion of FIG. 2B depicts the substrate 230, the substrate surface 233, the conductive layer 231, the first structurable layer 237, the first structurable layer surface 239, and the electrodes 235 after execution of the step 205. The middle portion of FIG. 2B depicts the substrate 230, the substrate surface 233, the conductive layer 231, the first structurable layer 237, the first structurable layer surface 239, the electrodes 235, and the structure boundaries 243 after execution of the step 207. The lower portion of FIG. 2B depicts the substrate 230, the substrate surface 233, the conductive layer 231, the first structurable layer 237, the first structurable layer surface 239, the electrodes 235, the structure boundaries 243, the second structurable layer 245, and the additional structure boundaries 243 after execution of the step 211. Some of the structure boundaries 243 and the additional structure boundaries 243 are depicted as being offset in the FIG. 2B.

FIG. 2C depicts various process steps executed in the example process flow 200 depicted in FIG. 2A. The upper portion of FIG. 2C depicts the substrate 230, the substrate surface 233, the conductive layer 231, the first structurable layer 237, the first structurable layer surface 239, the electrodes 235, the second structurable layer 245, and the structures 247 after execution of the step 213. The middle portion of FIG. 2C depicts the substrate 230, the substrate surface 233, the conductive layer 231, the first structurable layer 237, the first structurable layer surface 239, the electrodes 235, the second structurable layer 245, and the electrical contacts 101 after execution of the step 215. The lower portion of FIG. 2C depicts the substrate 230, the substrate surface 233, the conductive layer 231, and the electrical contacts 101 after execution of the step 217.

FIG. 2D depicts various process steps executed in the example process flow 200 depicted in FIG. 2A. The upper portion of FIG. 2D depicts the substrate 230, the substrate surface 233, the conductive layer 231, the electrical contacts 101, the tool 249, and the formable material 253 after execution of the step 219. The middle portion of FIG. 2D depicts the electrical contacts 101 and the electrical insulators 107 after execution of the step 221. The electrical contacts 101 have respected first and second electrical-contact surfaces 103, 105 respectively, substantially free of the electrical insulators 107. The lower portion of FIG. 2D depicts singulation lines 255 along which discrete electrical-contact assemblies 100 are singulated (as depicted in FIG. 1A-FIG. 1F).

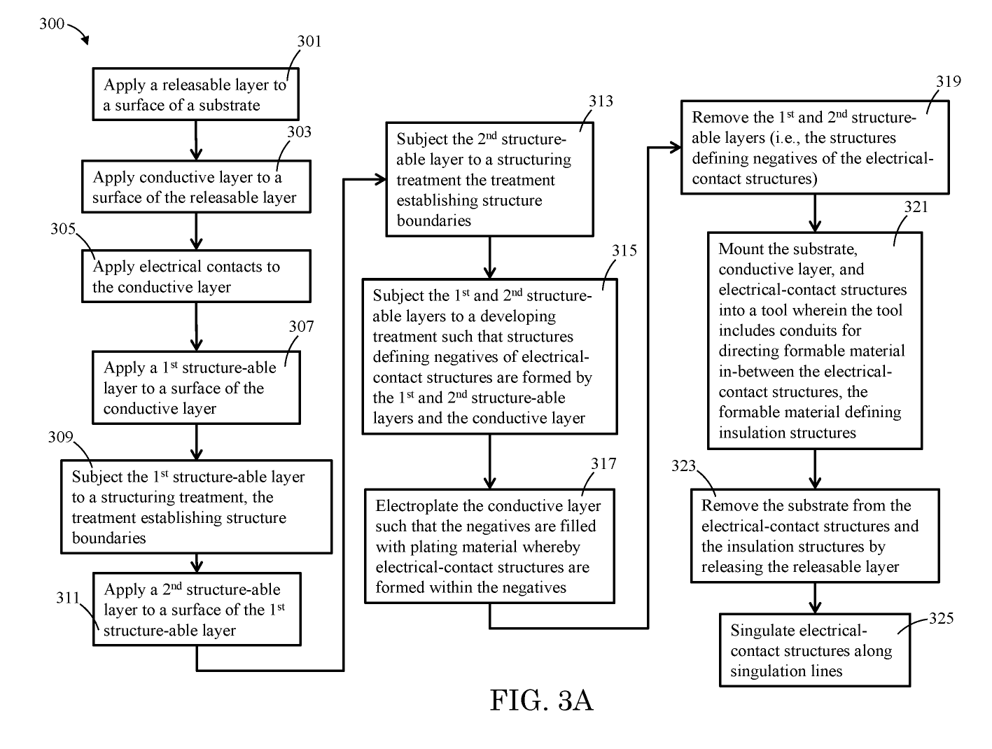

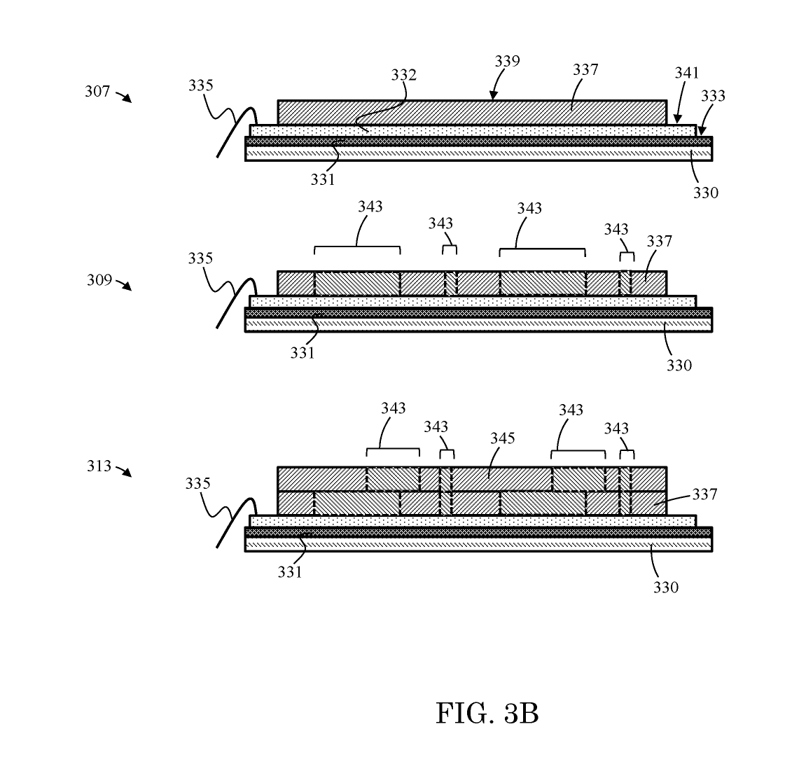

FIG. 3A depicts an example process flow for manufacturing electrical-contact assemblies. A method for manufacturing an electrical-contact assembly 300 includes a number of manufacturing the steps. In a first step 301 (as depicted in FIG. 3A) a releasable layer 331 is applied to a surface of the substrate 330.

In another step 303 a conductive layer 332 can be applied to the releasable layer 331. In some implementations the releasable layer 331 can facilitate adhesion of the conductive layer 332 to the substrate 330. In some implementations the adhesion properties (i.e., that facilities adhesion between the conductive layer 332 and the substrate 330) can be altered with an external stimulus. For example, in some implementations the releasable layer 331 can be implemented at a positive photoresist. In such instances the adhesion properties can be altered with irradiation (e.g., irrational with ultraviolet light). In such instances, the substrate 330 can be substantially transparent to the wavelengths of irradiation (e.g., to ultraviolet light). Releasable layer 331 can be implemented with different materials in other instances, for example, releasable layer 331 can be implemented as an adhesive that loses its adhesion properties with the application of heat. In such implementations the substrate 330 can be substantially transparent to wavelengths corresponding to the infrared spectrum. The conductive layer 331 can be at least partially composed of any number of suitable metals or their respective alloys (e.g., metals such as copper, nickel, iron, tin, silver, gold, zinc, palladium, rhodium, platinum) and/or metal alloys containing non-metals such as steel. The conductive layer 332 can be applied to the releasable layer 331 by any suitable means (e.g., sputtering or other deposition techniques). The substrate 330 can be any suitable material such as a glass wafer. In general, the substrate 330 should be substantially resistant to solutions (e.g., acids, developing solutions, and plating solutions) in subsequent steps.

In another step 305, electrodes 335 can be applied to a conductive layer surface 341 of the conductive layer 332. The electrodes 335 can be at least partially composed of any electrically conducting material such as any number of suitable metals or their respective alloys (e.g., metals such as copper, nickel, iron, tin, silver, gold, zinc, palladium, rhodium, platinum) and/or metal alloys containing non-metals such as steel. Application of the electrodes 335 to the conductive layer 332 can be accomplished by any suitable means (e.g., soldering).

In another step 307 a first structurable layer 337 can be applied to a surface of the conductive layer 341. The first structurable layer 337 can be at least partially composed of any material that can be structured (e.g., a photo-structurable material such as a photoresist). The first structurable layer 337 can be particularly thin, for example, in some implementations the first structurable layer 337 can be 17 microns thick, while in other implementations the first structurable layer 337 can be even less than 17 microns thick. Still further, in other implementations the first structurable layer 337 can be thicker, for example 50 microns or even hundreds of microns thick. The first structurable layer 337 can be applied to the conductive layer surface 341 as a foil in some implementations, while in other implementations the first structurable layer 337 can be applied with spin coating, evaporation, or any other suitable means apparent to a person of ordinary skill in the art in light of this disclosure.

In another step 309 the first structurable layer 337 can be subjected to a structuring treatment, where the treatment establishes structure boundaries 343. The structuring treatment can include irradiating the first structurable layer 337 with electromagnetic radiation (e.g., ultraviolet radiation and/or infrared radiation) in implementations where the first structurable layer 337 is implemented as a photoresist or other photo-structurable material. In such implementations the portions of the first structurable layer 337 that are irradiated with electromagnetic radiation can establish structure boundaries 343. The structure boundaries 343 can be positioned with patriotically high accuracy, for example, 5 microns or even less. The accuracy of the structure boundaries 343 positioning contributes to the accuracy in dimensioning and positioning of the electrical contacts 101.

In another step 311 a second structurable layer 345 can be applied to a surface of the first structurable layer 337. As above, the second structurable layer 345 can be at least partially composed of any material that can be structured (e.g., a photo-structurable material such as a photoresist). The second structurable layer 345 can be particularly thin, for example, in some implementations the second structurable layer 345 can be 17 microns thick, while in other implementations the second structurable layer 345 can be even less than 17 microns thick. Still further, in other implementations the second structurable layer 345 can be thicker, for example 50 microns or even hundreds of microns thick. The second structurable layer 345 can be applied to the first structurable layer surface 339 as a foil in some implementations, while in other implementations the second structurable layer 345 can be applied with spin coating, evaporation, or any other suitable means apparent to a person of ordinary skill in the art in light of this disclosure.

In another step 313 the second structurable layer 345 can be subjected to a structuring treatment, where the treatment establishes additional structure boundaries 343. The structure boundaries 343 can be positioned with patriotically high accuracy, for example, 5 microns or even less. The accuracy of the structure boundaries 343 positioning contributes to the accuracy in dimensioning and positioning of the electrical contacts 101. In some implementations some of the additional structure boundaries 343 can be established at an offset from the structure boundaries 343 within the first structurable layer 337. The structuring treatment can include irradiating the second structurable layer 345 with electromagnetic radiation (e.g., ultraviolet radiation and/or infrared radiation) in implementations where the second structurable layer 345 is implemented as a photoresist or other photo-structurable material. In such implementations the portions of the second structurable layer 345 that are irradiated with electromagnetic radiation can establish the additional structure boundaries 343.

In another step 315, the first and second structurable layers 337, 345, respectively are subjected to a developing treatment. The developing treatment can delineate negatives of electrical contacts 101. The negatives of the electrical contact structures are formed by the first and second structurable layers and the conductive layer 332. Generally, the developing treatment removes some material (e.g., the material that was subjected to the structuring treatment described above), the removed material forming the negatives, described above, of the electrical contacts 101.

In another step 317 the conductive layer 332 is subjected to an electroplating treatment whereby metal is deposited onto the conductive layer surface 341. The metal (i.e., plating material) can be any number of suitable metals or their respective alloys (e.g., metals such as copper, nickel, iron, tin, silver, gold, zinc, palladium, rhodium, platinum) and/or metal alloys containing non-metals such as steel. The step 317 is carried out until a desired thickness of metal is reached, in particular until the negatives (described above) are substantially fully occupied with plating material, wherein the plating material substantially fully occupying the negatives delineates the electrical contacts 101.

In another step 319, the first and second structurable layers 337, 345, respectively are removed. For example, in some implementations, the first and second structurable layers 337, 345, respectively are removed using acids. While in other implementations the first and second structurable layers 337, 345, respectively are removed using other solutions (e.g., bases or other solvents such as organic solvents).

In another step 321 the substrate 330, the conductive layer 332, and the electrical contacts 101 can be mounted into a tool 349. The tool 349 can contain conduits for directing formable material 353 (e.g., liquid polymers, resins or other molding compounds) in between the electrical contacts 101. In some implementations the formable material 353 can be directed into the tool 349 under pressure. In some implementations the formable material 353 can be directed in the tool 349 by using a vacuum. While in some implementations the formable material 353 can be directed into the tool 349 with the application of heat. The formable material 353 can be subsequently cured (e.g., by ultraviolet or thermal treatments). Accordingly, upon curing the formable material 353, the tool 349 can be removed.

In another step 323, the substrate 330 and the releasable layer 331 can be removed from the conductive layer 332, the electrical contacts 101, and the electrical insulators 107. While in other implementations the substrate 330 can be removed from the conductive layer 332, the electrical contacts 101 and the electrical insulators 107. In some implementations the substrate 330 and the conductive layer 332 can be removed mechanically (e.g., with the application of a shearing force) as would be apparent to a person of ordinary skill in the art in light of this disclosure. In other implementations the releasable layer 331 can be irradiated (e.g., with ultraviolet light and/or infrared radiation) as described above. Irradiation of the releasable layer 331 can alter adhesion between the substrate 330 and the conductive layer 332 such that the substrate 330 and the conductive layer 332 are separated from each other. This can be an advantage in various implementations. Subsequent to separation of the substrate 330 and the releasable layer 331 from the conductive layer 332, the electrical contacts 101, and the electrical insulators 107, the conductive layer 332 can be removed by other treatments (e.g., via grinding, polishing or by chemical methods such as etching with acidic or caustic solutions).

In some implementations, in another step 325 the electrical contacts 101 are singulated into discrete electrical-contact assemblies 100 by techniques known to a person of ordinary skill in the art in light of this disclosure.

FIG. 3B depicts various process steps executed in the example process flow 300 depicted in FIG. 3A. The upper portion of FIG. 3B depicts the substrate 330, the substrate surface 333, the releasable layer 331, the conductive layer 332, the first structurable layer 337, the first structurable layer surface 339, and the electrodes 335 after execution of the step 307. The middle portion of FIG. 3B depicts the substrate 330, the substrate surface 333, the releasable layer 331, the conductive layer 332, the first structurable layer 337, the first structurable layer surface 339, the electrodes 335, and the structure boundaries 343 after execution of the step 309. The lower portion of FIG. 3B depicts the substrate 330, the substrate surface 333, the releasable layer 331, the conductive layer 332, the first structurable layer 337, the first structurable layer surface 339, the electrodes 335, the structure boundaries 343, the second structurable layer 345, and the additional structure boundaries 343 after execution of the step 313. Some of the structure boundaries 343 and the additional structure boundaries 343 are depicted as being offset in the FIG. 3B.

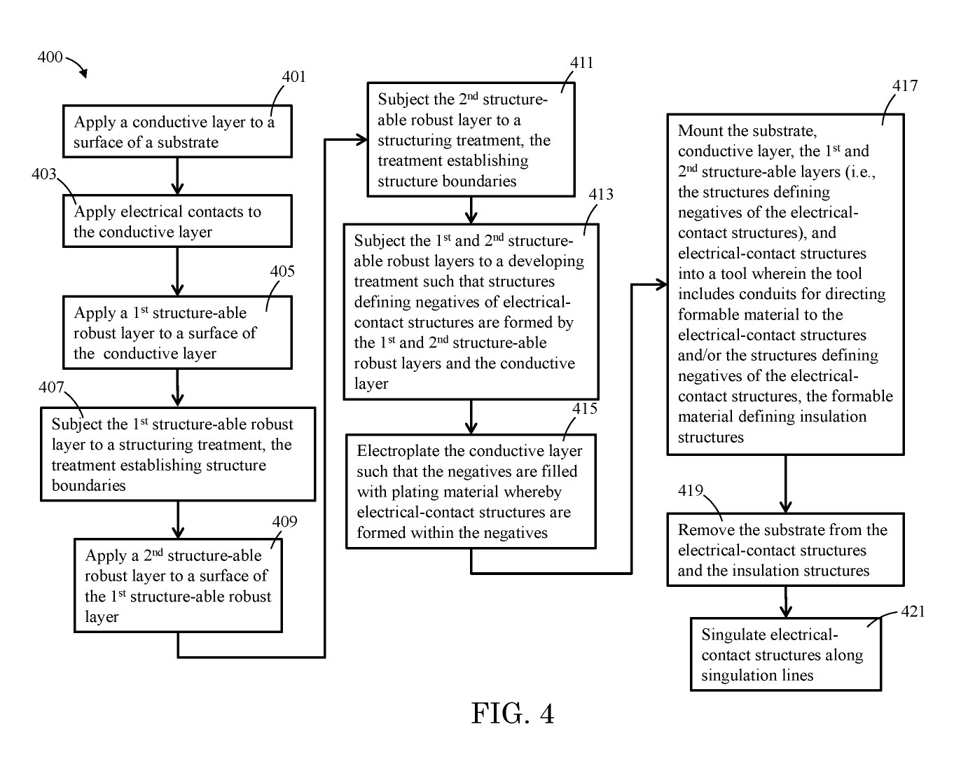

FIG. 4 depicts an example process flow for manufacturing electrical-contact assemblies. A method for manufacturing an electrical-contact assembly 400 includes a number of manufacturing the steps. In a first step 401 (as depicted in FIG. 4) a conductive layer can be applied to a substrate. The conductive layer can be at least partially composed of any number of suitable metals or their respective alloys (e.g., metals such as copper, nickel, iron, tin, silver, gold, zinc, palladium, rhodium, platinum) and/or metal alloys containing non-metals such as steel. The conductive layer can be applied to the substrate by any suitable means (e.g., sputtering or other deposition techniques). The substrate can be any suitable material such as a glass wafer. In general, the substrate should be substantially resistant to solutions (e.g., acids, developing solutions, and plating solutions) in subsequent steps.

In another step 403, an electrical contact can be applied to a surface of the conductive layer. The electrical contact can be at least partially composed of any electrically conducting material such as any number of suitable metals or their respective alloys (e.g., metals such as copper, nickel, iron, tin, silver, gold, zinc, palladium, rhodium, platinum) and/or metal alloys containing non-metals such as steel. Application of the electrical contact to the conductive layer can be accomplished by any suitable means (e.g., soldering).

In another step 405 a first structurable layer can be applied to a surface of the conductive layer. The first structurable layer can be at least partially composed of any material that can be structured (e.g., a photo-structurable material such as a photoresist). The first structurable layer can be particularly thin, for example, in some implementations the first structurable layer can be 17 microns thick, while in other implementations the first structurable layer can be even less than 17 microns thick. Still further, in other implementations the first structurable layer can be thicker, for example 50 microns or even hundreds of microns thick. The first structurable layer can be applied to the conductive layer surface as a foil in some implementations, while in other implementations the first structurable layer can be applied with spin coating, evaporation, or any other suitable means apparent to a person of ordinary skill in the art in light of this disclosure.

In another step 407 the first structurable layer can be subjected to a structuring treatment, where the treatment establishes structure boundaries. The structuring treatment can include irradiating the first structurable layer with electromagnetic radiation (e.g., ultraviolet radiation and/or infrared radiation) in implementations where the first structurable layer is implemented as a photoresist or other photo-structurable material. In such implementations the portions of the first structurable layer that are irradiated with electromagnetic radiation can establish structure boundaries. The structure boundaries can be positioned with patriotically high accuracy, for example, 5 microns or even less. The accuracy of the structure boundaries positioning contributes to the accuracy in dimensioning and positioning of the electrical contacts 101.

In another step 409 a second structurable layer can be applied to a surface of the first structurable layer. As above, the second structurable layer can be at least partially composed of any material that can be structured (e.g., a photo-structurable material such as a photoresist). The second structurable layer can be particularly thin, for example, in some implementations the second structurable layer can be 17 microns thick, while in other implementations the second structurable layer can be even less than 17 microns thick. Still further, in other implementations the second structurable layer can be thicker, for example 50 microns or even hundreds of microns thick. The second structurable layer can be applied to the first structurable layer surface as a foil in some implementations, while in other implementations the second structurable layer can be applied with spin coating, evaporation, or any other suitable means apparent to a person of ordinary skill in the art in light of this disclosure.

In another step 411 the second structurable layer can be subjected to a structuring treatment, where the treatment establishes additional structure boundaries. The structure boundaries can be positioned with patriotically high accuracy, for example, 5 microns or even less. The accuracy of the structure boundaries positioning contributes to the accuracy in dimensioning and positioning of the electrical contacts 101. In some implementations some of the additional structure boundaries can be established at an offset from the structure boundaries within the first structurable layer. The structuring treatment can include irradiating the second structurable layer with electromagnetic radiation (e.g., ultraviolet radiation and/or infrared radiation) in implementations where the second structurable layer is implemented as a photoresist or other photo-structurable material. In such implementations the portions of the second structurable layer that are irradiated with electromagnetic radiation can establish the additional structure boundaries.

In another step 413, the first and second structurable layers, respectively are subjected to a developing treatment. The developing treatment can delineate negatives of electrical contacts 101. The negatives of the electrical contact structures are formed by the first and second structurable layers and the conductive layer. Generally, the developing treatment removes some material (e.g., the material that was subjected to the structuring treatment described above), the removed material forming the negatives, described above, of the electrical contacts 101.

In another step 415 the conductive layer is subjected to an electroplating treatment whereby metal is deposited onto the surface of the conductive layer. The metal (i.e., plating material) can be any number of suitable metals or their respective alloys (e.g., metals such as copper, nickel, iron, tin, silver, gold, zinc, palladium, rhodium, platinum) and/or metal alloys containing non-metals such as steel. The step 415 is carried out until a desired thickness of metal is reached, in particular until the negatives (described above) are substantially fully occupied with plating material, wherein the plating material substantially fully occupying the negatives delineates the electrical contacts 101.

In another step 417, the substrate, the conductive layer, the first and second robust structurable layers, and the electrical contacts 101 can be mounted into a tool. The tool can contain conduits for directing formable material (e.g., liquid polymers, resins or other molding compounds) in between the electrical contacts 101. In some implementations the formable material can be directed into the tool under pressure. In some implementations the formable material can be directed in the tool by using a vacuum. While in some implementations the formable material can be directed into the tool with the application of heat. The formable material can be subsequently cured (e.g., by ultraviolet or thermal treatments). Accordingly, upon curing the formable material, the tool can be removed.

In another step 419, the substrate and the conductive layer can be removed from the electrical contacts 101 and the electrical insulators 107. While in other implementations the substrate can be removed from the conductive layer, the electrical contacts 101 and the electrical insulators 107. In some implementations the substrate and the conductive layer, and/or the substrate can be removed mechanically (e.g., with the application of a shearing force) as would be apparent to a person of ordinary skill in the art in light of this disclosure. Subsequent to separation of the substrate from the conductive layer, the electrical contacts 101, and the electrical insulators 107, the conductive layer can be removed by other treatments (e.g., via grinding, polishing or by chemical methods such as etching with acidic or caustic solutions).

In some implementations, in another step 421 the electrical contacts 101 are singulated into discrete electrical-contact assemblies 100 by techniques known to a person of ordinary skill in the art in light of this disclosure.

Various modifications can be made within the spirit of this disclosure. For example, in various manufacturing steps have been described above; however, the sequences and frequency of the described manufacturing steps can be modified. Accordingly, other implementations are within the scope of the claims.

1. An electrical-contact assembly, the assembly comprising:
a plurality of electrical contacts each of which is substantially electrically conductive and has a first electrical-contact surface and a second electrical-contact surface respectively disposed on opposing sides of the electrical contact;
wherein the plurality of electrical contacts are interposed by a plurality of electrical insulators that are substantially electrically insulating.

2. The electrical-contact assembly of claim 1, wherein the plurality of electrical insulators are at least partially composed of a mechanically robust layer.

3. The electrical-contact assembly of claim 1, wherein at least one of the electrical-contact structures includes offset first and second electrical-contact surfaces.

4. The electrical-contact assembly of claim 1, wherein the electrical insulators are at least partially composed of curable epoxy resin.

5. The electrical-contact assembly of claim 1, wherein at least one of the electrical insulators extends around at least one first electrical-contact surface, the at least one electrical insulator forming sidewalls, the sidewalls delineating a chamber associated with the at least one first electrical-contact surface.

6. The electrical-contact assembly of claim 2, wherein at least one of the electrical-contacts includes offset first and second electrical-contact surfaces.

7. The electrical-contact assembly of claim 2, wherein the mechanically robust structureble layer includes an additive dispersed within a photo-resist.

8. The electrical-contact assembly as in claim 2, wherein at least one sidewall element is mounted on a surface of the mechanically robust structurable layer, the at least one sidewall element delineating a chamber associated with at least one first electrical-contact surface.

9. The electrical-contact assembly as in claim 1, wherein at least one of the first electrical-contact surfaces includes an active optoelectronic component electrically connected to the at least one first electrical-contact surface.

10. The electrical-contact assembly as in claim 9, wherein the sidewall element is substantially non-transparent to electromagnetic radiation emitted by or detectable by the active optoelectronic component.

11. The electrical-contact assembly as in claim 9, wherein the electrical insulator is substantially non-transparent to electromagnetic radiation emitted by or detectable by the active optoelectronic component.

12. The electrical-contact assembly as in claim 9, wherein the active optoelectronic component includes an emitter.

13. The electrical-contact assembly as in claim 9, wherein the active optoelectronic component includes a detector.

14. The electrical-contact assembly as in claim 9, wherein the active optoelectronic component includes an overmold of transparent material.

15. The electrical-contact assembly in claim 14, wherein a surface of the overmold delineates a surface profile of an optical element.

16. A method for manufacturing an electrical-contact assembly, the method comprising:
applying a conductive layer to a surface of a substrate;
applying electrodes to the conductive layer;
applying a first structurable layer to a surface of the conductive layer; and
subjecting the first structurable layer to a structuring treatment, the treatment establishing structure boundaries.

17. The method for manufacturing the electrical-contact assembly as in claim 16, further comprising:
subjecting the first structurable layer to a developing treatment such that
structures defining negatives of electrical contacts are formed by the first structurable layer and the conductive layer;
electroplating the conductive layer such that the negatives are filled with plating material whereby electrical contacts are formed within the negatives;
removing the first structurable layers;
mounting the substrate, conductive layer, and electrical contacts into a tool wherein the tool includes conduits for directing formable material in-between the electrical contacts, the formable material defining electrical insulators;
removing the substrate from the conductive layer, the electrical contacts and the electrical insulators; and
singulating electrical contacts along singulation lines.

18. The method for manufacturing the electrical-contact assembly as in claim 16, further comprising:
applying a second structurable layer to a surface of the first structurable layer;
subjecting the second structurable layer to a structuring treatment, the treatment establishing structure boundaries;
subjecting the first and second structurable layers to a developing treatment such that structures defining negatives of electrical contacts are formed by the first and second structurable layers and the conductive layer;
electroplating the conductive layer such that the negatives are filled with plating material whereby electrical contacts are formed within the negatives;
removing the first and second structurable layers;
mounting the substrate, conductive layer, and electrical contacts into a tool wherein the tool includes conduits for directing formable material in-between the electrical contacts, the formable material defining electrical insulators;
removing the substrate from the conductive layer, the electrical contacts and the electrical insulators; and
singulating electrical contacts along singulation lines.

19. The method for manufacturing the electrical-contact assembly as in claim 17, wherein the first structurable layer is a robust structurable layer.

20. The method for manufacturing the electrical-contact assembly as in claim 18, wherein the first structurable layer and second structurable layer are robust structurable layers.

21. The method as in claim 16, further comprising:
applying a releasable layer to a surface of the substrate, the releasable layer being between the conductive layer and the substrate; and
removing the substrate from the electrical contacts and the electrical insulators by releasing the releasable layer.
